(19) United States
(12) Patent Application Publication
(10) Pub. No.: US 2006/0151855 A1
(43) Pub. Date: Jul. 13, 2006

(54) Semiconductor device and method of manufacturing the same

(76) Inventors: Masahiro Kiyotoshi, Sagamihara-shi (JP); Atsuko Kawasaki, Yokohama-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/285,156

(22) Filed: Nov. 23, 2005

(30) Foreign Application Priority Data
Nov. 25, 2004 (JP) 2004-340794

(51) Int. Cl. H01L 21/76; H01L 29/06

(52) U.S. Cl. 257/618; 438/424

(57) ABSTRACT

A semiconductor device includes a semiconductor substrate including an isolation trench provided on a surface thereof, an isolation film provided in the isolation trench, the isolation film including a coating film and a silicon oxide film provided on the coating film, and an oxide film provided between the isolation trench and the isolation film, the oxide film having a thickness such that a portion on a side surface of the isolation trench corresponding to an interface portion between the coating film and the silicon oxide film is thicker than other portion on the side surface.

### CROSS-REFERENCE TO RELATED APPLICATIONS

This application is based upon and claims the benefit of priority from prior Japanese Patent Application No. 2004-340794, filed Nov. 25, 2004, the entire contents of which are incorporated herein by reference.

### BACKGROUND OF THE INVENTION

1. Field of the Invention

The present invention relates to a semiconductor device and a method of manufacturing the same using trench type isolation, especially, shallow trench isolation (STI).

2. Description of the Related Art

The miniaturization of LSI devices is intended to improve performance of device by high integration (for example, the operating speed and the low power consumption) and decrease the manufacturing cost. Recently, the design rule has been declined to substantially 0.1 micrometer in the mass production. The miniaturization technology is now implemented with much difficulty, its down-sizing to 0.1 micrometer or lower will be destined. So far, the miniaturization of logic device comes to a stage of the development where the gate length of a test piece is as small as 30 nm.

To achieve large-scale integration, it is important to miniaturize an isolation region which occupies almost a half of the device area. Recently, the STI technology is used as a small isolation region forming method. The STI technology is such a technology that forms the isolation region by filling a trench (isolation trench) formed by anisotropic etching with an insulating film (isolation film).

Using such an STI technology, the isolation region having trench width about 90 nm to 70 nm is realized. Even in a memory requiring high integration, an active area width of transistor and isolation region width are also reaching to about equal to 0.1 micrometer or less as ranging from 90 nm to 70 nm. Therefore, the miniaturization of the isolation region of the memory is also becoming a matter of importance.

As the miniaturization is advanced, the difficulty for forming the isolation region increases. The reason is as follows. The isolation ability (the degree of insulation) is determined by the effective distance between two adjacent elements. The effective distance is determined by the minimum distance of peripheral length of the trench along the path from one side wall of the trench to other side wall of the trench via a bottom of the trench. It is thus essential for not decreasing the isolation ability to maintain the effective distance, i.e., the depth of isolation trench even when the device is miniaturized. The width of isolation trench becomes smaller as the miniaturization is advanced. The aspect ratio of the isolation trench is also increased as the miniaturization is advanced. As a result, as the miniaturization is advanced, the difficulty of forming the isolation region becomes higher.

At the present day, there is a high density plasma (HDP) CVD process as one of the typical methods for forming the isolation film. When the HDP CVD process is used for forming a silicon oxide film (HDP silicon oxide film) in the isolation trench of a generation type equal to 0.1 micrometer or less, the aspect ratio is equal to 3 or higher. Therefore, it becomes very difficult to form the HDP silicon oxide film which is free from a void (not filled region) in the isolation trench. The void in the HDP silicon oxide film in the isolation trench may causes decline of insulation ability.

Also focused today is a coating film such as a spin on glass (SOG) as the isolation film. One of the reasons is that the coating film has fluidity, then, the isolation trench having a high aspect can easily filled with the coating film. Another reason is that the coating film is useful for realizing the isolation film without the void or seamless isolation film.

The coating film may contain many impurities. The impurities contribute to the increase in the fluidity of the coating film. The density of the isolation film obtained by baking the coating film is influenced by the impurities. Therefore, resistance to wet etching of the coating film used as the isolation film will be lowered.

Semiconductor device, peculiarly, logic device comprises a plurality of gate oxide films which are different in the thickness (a multi gate oxide). The multi gate oxide is formed as follows.

As a gate oxide film having a thickness is formed, thereafter, unnecessary portion of the gate oxide film is removed by wet etching. Next, a gate oxide film having a different thickness is formed, thereafter, unnecessary portion of the gate oxide film is removed by wet etching. Those forming and partial removing of the gate oxide film is repeated by the number of kinds of film thickness, thereby, the multi gate oxide is formed.

However, as mentioned above, the resistance to wet etching of the coating film is low, so, the coating film is etched by repeating the wet etching. Thereby, the isolation ability between two adjacent elements will be lowered.

Then, to avoid the disadvantage, hybrid filling process is much considered. The hybrid filling process comprises a step of filling the isolation trench with the coating film, a step of etching back the coating film by dry process, and a step of filling the removed portion in the isolation trench with a densified insulating film such as an HDP silicon oxide film.

However, the conventional hybrid filling process (Jpn. Pat. Appln. KOKAI Publication No. 2002-203895) easily causes a decline of device characteristics. The reasons have not been clear, but following (1)-(3) are considered as the reasons.

(1) Etching back the coating film uniformly is difficult.

(2) When the coating film is etched back by dry process, reaction products adhered on the inner surface of the isolation trench. The reaction products are removed by wet etching. The wet etching also etches the coating film. Such the etching more than necessary of the coating film causes a failure of filling of STI with the HDP silicon oxide film, and it turns out to reduce the device characteristics such as breakdown voltage.

(3) In a gate first formed structure, a step of etching back the coating film by dry etching gives plasma damage to an edge of the gate oxide film. This easily causes the decline of the characteristics.

### BRIEF SUMMARY OF THE INVENTION

According to an aspect of the present invention, there is provided a semiconductor device comprising: a semiconductor substrate including an isolation trench provided on a surface thereof; an isolation film provided in the isolation trench, the isolation film including a coating film and a silicon oxide film provided on the coating film; and an oxide film provided between the isolation trench and the isolation film, the oxide film having a thickness such that a portion on a side surface of the isolation trench corresponding to an interface portion between the coating film and the silicon oxide film is thicker than other portion on the side surface.

According to another aspect of the present invention, there is provided a semiconductor device comprising: a semiconductor substrate including an isolation trench provided on a surface thereof; an isolation film provided in the isolation trench, the isolation film including a coating film and a silicon oxide film provided on the coating film; and a liner film provided between the isolation trench and the isolation film, the liner film having a thickness such that a portion on a upper surface of the isolation trench decreases upward.

According to an aspect of the present invention, there is provided a method of manufacturing a semiconductor device comprising: forming an isolation trench on a surface of a semiconductor substrate; filling the isolation trench with a coating film; heating the coating film under at least one of condition that shrinkage ration of the coating film is not higher than a predetermined value and condition that film density of the coating film is not higher than a predetermined value; removing an upper portion of the coating film in the isolation trench by etch back using wet etching; forming a silicon oxide film on the semiconductor substrate so as to fill the isolation trench; and planarizing the silicon oxide film by CMP process.

### BRIEF DESCRIPTION OF THE SEVERAL VIEWS OF THE DRAWING

FIG. 1 is a cross sectional view showing a step in a method of manufacturing a semiconductor device according to a first embodiment of the present invention;

FIG. 2 is a cross sectional view showing a step of the method of manufacturing the semiconductor device according to the first embodiment of the invention following the FIG. 1;

FIG. 3 is a cross sectional view showing a step of the method of manufacturing the semiconductor device according to the first embodiment of the invention following the FIG. 2;

FIG. 4 is a cross sectional view showing a step of the method of manufacturing the semiconductor device according to the first embodiment of the invention following the FIG. 3;

FIG. 5 is a cross sectional view showing a step of the method of manufacturing the semiconductor device according to the first embodiment of the invention following the FIG. 4;

FIG. 6 is a cross sectional view showing a step of the method of manufacturing the semiconductor device according to the first embodiment of the invention following the FIG. 5;

FIG. 7 is a cross sectional view showing a step of the method of manufacturing the semiconductor device according to the first embodiment of the invention following the FIG. 6;

FIGS. 8A and 8B are cross sectional views of the semiconductor device according to the first embodiment of the invention;

FIG. 9 is a graph showing the relationship between temperature for thermal treatment and wet etching rate ratio;

FIG. 10 is a graph showing the relationship between the temperature for thermal treatment and the film shrinkage;

FIG. 11 is a graph showing the relationship between temperature for thermal treatment and film density;

FIG. 12 is a cross sectional view showing a step in a method of manufacturing a semiconductor device according to a second embodiment of the present invention;

FIG. 13 is a cross sectional view showing a step of the method of manufacturing the semiconductor device according to the second embodiment of the invention following the FIG. 12;

FIG. 14 is a cross sectional view showing a step of the method of manufacturing the semiconductor device according to the second embodiment of the invention following the FIG. 13;

FIG. 15 is a cross sectional view showing a step of the method of manufacturing the semiconductor device according to the second embodiment of the invention following the FIG. 14;

FIG. 16 is a cross sectional view showing a step of the method of manufacturing the semiconductor device according to the second embodiment of the invention following the FIG. 15;

FIG. 17 is a cross sectional view showing a step of the method of manufacturing the semiconductor device according to the second embodiment of the invention following the FIG. 16;

FIG. 18 is a cross sectional view showing a step of the method of manufacturing the semiconductor device according to the second embodiment of the invention following the FIG. 17;

FIGS. 19A and 19B are cross sectional views of the semiconductor device according to the second embodiment of the invention;

FIG. 20 is a cross sectional view showing a step in a method of manufacturing a semiconductor device for comparison;

FIG. 21 is a cross sectional view showing a step in a method of manufacturing a semiconductor device according to a third embodiment of the invention;

FIG. 22 is a cross sectional view showing a step of the method of manufacturing the semiconductor device according to the third embodiment of the invention following the FIG. 21;

FIG. 23 is a cross sectional view showing a step of the method of manufacturing the semiconductor device according to the third embodiment of the invention following the FIG. 22;

FIG. 24 is a cross sectional view showing a step of the method of manufacturing the semiconductor device according to the third embodiment of the invention following the FIG. 23;

FIG. 25 is a cross sectional view showing a step of the method of manufacturing the semiconductor device according to the third embodiment of the invention following the FIG. 24;

FIG. 26 is a cross sectional view showing a step of the method of manufacturing the semiconductor device according to the third embodiment of the invention following the FIG. 25;

FIGS. 27A and 27B are cross sectional views of the semiconductor device according to the third embodiment of the invention;

FIG. 28 is a cross sectional view showing a drawback in the method of manufacturing the semiconductor device for comparison example;

FIG. 29 is a cross sectional view showing a drawback in the method of manufacturing the semiconductor device for comparison example;

FIG. 30 is a cross sectional view showing a drawback in the method of manufacturing the semiconductor device for comparison example;

FIG. 31 is a cross sectional view showing a drawback in the method of manufacturing the semiconductor device for comparison example; and

FIG. 32 is a cross sectional view showing a drawback in the method of manufacturing the semiconductor device for comparison example.

### DETAILED DESCRIPTION OF THE INVENTION

Hereinafter, embodiments of the present invention will be described with reference to the drawings.

### First Embodiment

FIGS. 1 to 7 are cross sectional views showing steps of a method of manufacturing a semiconductor device according to a first embodiment of the present invention.

The present embodiment explains a case where an STI is formed before a gate oxide film and a gate electrode are formed on a silicon substrate.

The manufacturing method of present embodiment comprises a step of filling a shallow trench with a polysilazane film, a step of removing an upper portion of the polysilazane film in the shallow trench by etching back using wet etching technique, and a step of filling the shallow trench on the polysilazane film.

By the manufacturing method, a structure which allows an upper portion of the STI to be protected by the HDP silicon oxide film is obtained. Thereby, the etching of polysilazane film (thinning of STI) is suppressed even in a case where STI is etched a plurality of times as in the multi gate oxide process. The method of present embodiment will be explained in more detail.

[FIG. 1]

At first, a thermal silicon oxide film 102 is formed on a silicon substrate 101, thereafter, a silicon nitride film 103 to be a CMP stopper is formed on the thermal silicon oxide film 102. Thickness of the thermal silicon oxide film 102 is, for example, 5 nm, thickness of the silicon nitride film 103 is, for example, 180 nm.

Next, a CVD silicon oxide film to be a mask in the RIE (Reactive Ion Etching) process is formed on an entire surface of the substrate, thereafter, a photo resist film is applied on the CVD silicon oxide film.

Next, the photo resist film is processed by conventional lithographic process, thereafter, the CVD silicon oxide film is etched by the RIE process using the processed photo resist film (resist pattern), thus a hard mask is formed. Thereafter, the photo resist film is removed by ashing process and etching process with a sulfuric acid/hydrogen peroxide mixture solution.

Next, the silicon nitride film 103, the thermal silicon oxide film 102, and the silicon substrate 101 are etched sequentially by the RIE process using the hard mask (the CVD silicon oxide film) as a mask, thus a trench (shallow trench) of 350 nm depth is formed on the surface of the silicon substrate 101. Thereafter, the hard mask is selectively removed by a vapor of fluoric acid.

Next, an inner surface (side surface and bottom surface) of the shallow trench is thermally oxidized, thus a thermal silicon oxide film 104 of 3 nm thickness is formed on the inner surface.

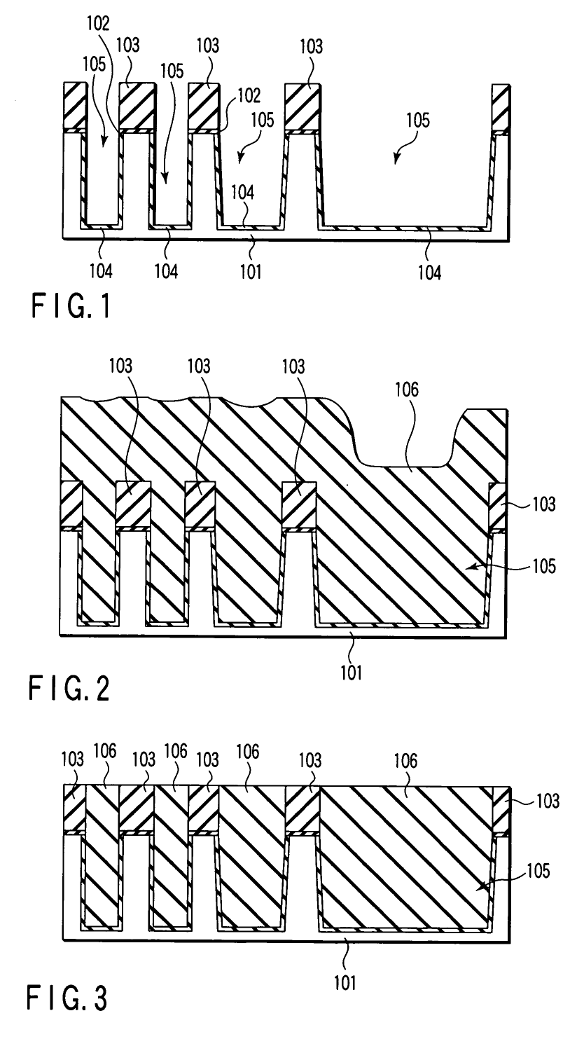

After the foregoing steps, an isolation trench 105 for STI including the shallow trench and the thermal silicon oxide film which covers the inner surface of the shallow trench. FIG. 1 illustrates the isolation trenches 105 including three types of trench regions which are different in isolation width.

[FIG. 2]

Next, a polysilazane film 106 having a thickness of 650 nm is formed on the entire surface by spin coating process. The concrete process of the polysilazane film 106 is performed as follows.

First, perhydride silazane polymer (perhydro-polysilazane) [(SiH₂NH)ₙ] is dispersed into xylene, dibutyl ether, or the like, thus perhydride silazane polymer solution is generated, thereafter, the perhydride silazane polymer solution is applied on the surface of the silicon substrate 101 by spin coating process. Because, it is a application of liquid, the isolation trench 105 having a high aspect ratio of the present embodiment is filled with a coating film including the perhydride silazane polymer without generating a void (unfilled region) or seam (unfilled joint region).

The condition of the spin coating process is, for example, spin rate of the silicon substrate 101 is 1000 rpm, spin time of the silicon substrate 101 is 30 seconds and drop quantity of the perhydride silazane polymer solution is 2 cc. Under the condition, the polysilazane film 106 having a thickness of 650 nm is obtained.

Next, a predetermined heat treatment is applied to the coating film, thus the coating film is changed into the polysilazane film 106 having a low density of impurities.

More specifically, at first, the silicon substrate 101 on which the coating film is formed is heated on a hot plate at 150° C., thereafter, the silicon substrate 101 is baked for three minutes in an inert gas atmosphere, thus solvent in the perhydride silazane polymer solution is evaporated. In the state, a few to some tens percent of carbons or hydrocarbons which are derive from the solvent remains as the impurities in the polysilazane film 106.

Next, a heating treatment is applied to the coating film in a water vapor atmosphere at a temperature from 250° C. to 350° C. By the heat treatment, the carbons or hydrocarbons in the coating film are removed, further, most of Si—N bonds in the coating film are changed into Si—O bonds. This reaction takes a progress as in expressed below.
SiH₂NH+2O→SiO₂+NH₃.

By the reaction and thermal shrinkage, the coating film is densified and turned to a polysilazane film 106 (insulation film) which can be processed by CMP process.

[FIG. 3]

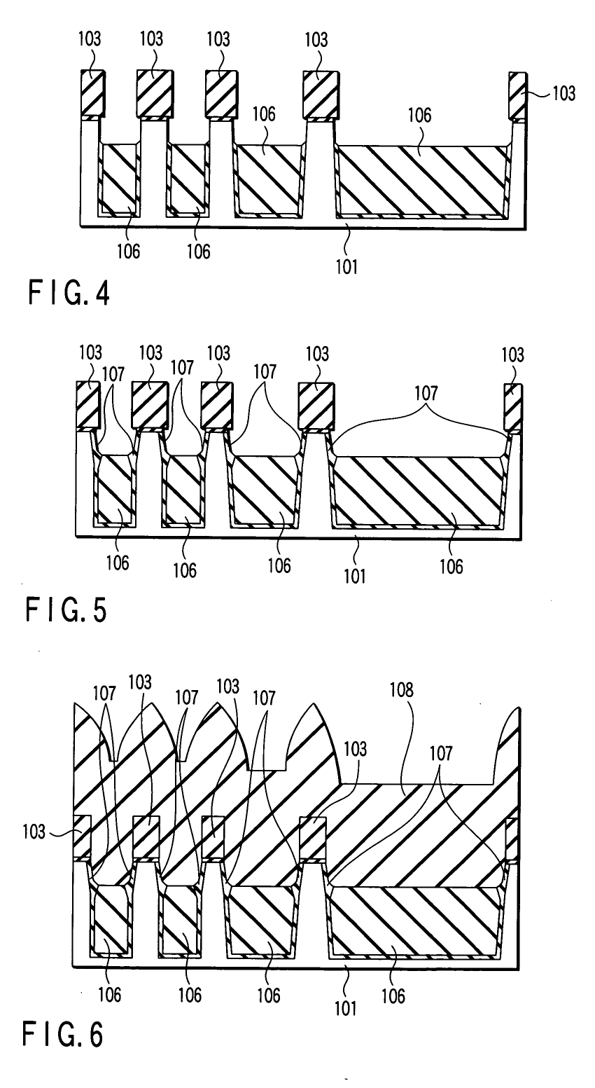

Next, the polysilazane film 106 is polished by CMP process using the silicon nitride film 103 as a stopper, thus the polysilazane film 106 remains only in the isolation trench 105.

[FIG. 4]

Next, the polysilazane film 106 is etched back 300 nm by wet etching using a 100:1 diluted fluoric acid. At this time, it is desired that the polysilazane film 106 in the plurality of trench regions having the different isolation widths of the isolation trench is etched back at the same rate so that the isolation trench is easily filled an HDP silicon oxide film 108 in a step of FIG. 6 which will be mentioned later.

Because, if the polysilazane film 106 in the narrow isolation trench 105 is etched back more than the polysilazane film 106 in the wide isolation trench 105, the wide isolation trench 105 is not etched back enough in depth or the narrow isolation trench 105 is excessively etched back in depth, therefore, it is supposed that HDP silicon oxide film is not sufficiently embedded.

In the present embodiment, as the polysilazane film 106 is heated under the water vapor atmosphere ranging from 250° C. to 350° C. in the step of FIG. 2, the polysilazane film 106 in the plurality of trench regions having the different isolation widths of the isolation trench is etched back at the same rate. This point will be explained below in more detail.

The wet etching rate heavily depends on the density of the polysilazane film 106. The density of the polysilazane film 106 heavily depends on the temperature of the heat treatment in the water vapor atmosphere.

FIG. 9 illustrates the relationship between the temperature of heat treatment to the polysilazane film (heat treatment temperature) and the wet etching rate ration of the polysilazane film in the narrow trench (about 70 nm) and wide trench (about 1 micrometer) to the thermal silicon oxide film (selectivity). The heat treatment is performed in the water vapor atmosphere. The etching solution is a 100:1 diluted fluoric acid solution.

FIG. 10 illustrates the relationship between the heat treatment temperature and the density of the polysilazane film.

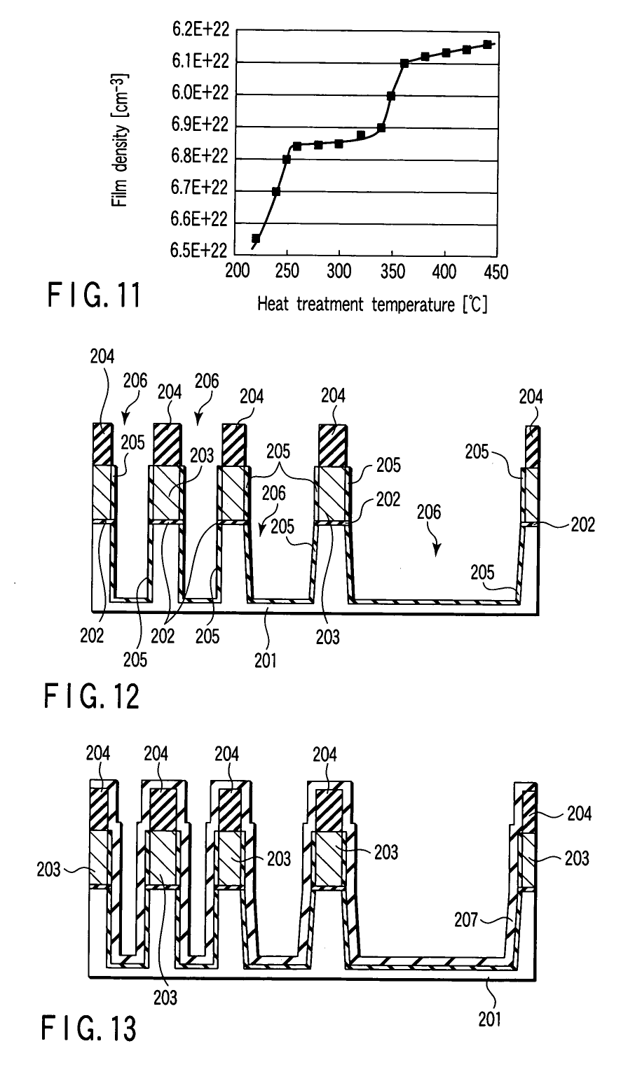

FIG. 11 illustrates the relationship between the heat treatment temperature and the thermal shrinkage of the polysilazane film.

It is understood from FIG. 9 that the selectivity of the polysilazane film to the thermal silicon oxide film becomes equal to 10:1 or higher and the polysilazane film in the narrow and wide trench can be wet etched at the same rate by setting the heat treatment temperature in a range of 250° C. to 350° C. The same effect is also obtained when the thermal silicon oxide film is replaced by a CVD silicon oxide film.

It is understood from FIG. 10 that the shrinkage of the polysilazane film can be equal to 10% or less by setting the heat treatment temperature in the range of 250° C. to 350° C. In other words, in order to etch the polysilazane film in the narrow and wide trench by wet at the same rate, it is revealed that the polysilazane film should be heated in the water vapor atmosphere under the condition that the density of the polysilazane film becomes equal to 6.0×10²² cm⁻³ or less.

That is, the inventors have found that the polysilazane film which is a kind of SOG film can be etched back at the same rate regardless of the width of the shallow trench and can be etched at a high selectivity of 10 times or more than the thermal silicon oxide film or the CVD silicon oxide film by contriving the heat treatment for the polysilazane film.

In a case where the heat treatment temperature is lower than 350° C., the wet etching rate of the polysilazane film which is filled in the narrow trench and the wet etching rate of the polysilazane film which is filled in the wide trench are same, however, in a case where the heat treatment temperature is lower than 250° C., the wet etching rate of the polysilazane film is too fast, thus it is very difficult to control the processing shape.

Here, in a case where the heat treatment in the water vapor atmosphere at 280° C. for one hours is performed as the heat treatment for the polysilazane film, density of polysilazane film 106: 5.9×10²² cm⁻³, shrinkage of polysilazane film 106: 7.5%, selectivity of wet etching using 100:1 diluted fluoric acid solution to thermal silicon oxide film: 20 are obtained.

The polysilazane film 106 is etched back by wet etching after the heat treatment under the above conditions, as the result, the same rate of etching is realized regardless of the width of the isolation trench, and the remained film thickness of the polysilazane films 106 can be approximately 250 nm.

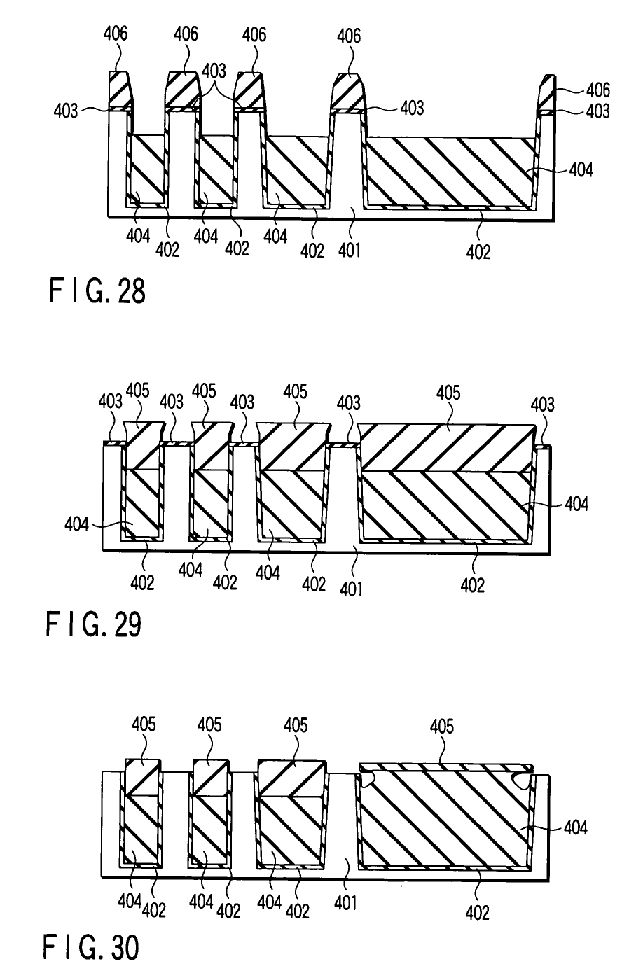

FIGS. 28 and 29 are cross sectional views of comparison samples where the polysilazane films are etched back by dry etching process such as RIE process.

As shown in FIG. 28, in a case where the etch back of the polysilazane films 404 is performed by dry process, silicon nitride films 406 as the CMP stopper is also etched. Therefore, the controllability of the CMP falls when the CMP is repeated two times.

Further, as shown in FIG. 29, the sidewall of STI is turned to a reverse taper shape. Therefore, a polycrystalline silicon film to be a gate electrode tends to remain in the portion of the inverse taper shape. This easily causes a short failure.

In FIGS. 28 and 29, 401 indicate a silicon substrate, 402 and 403 indicate thermal silicon oxide films.

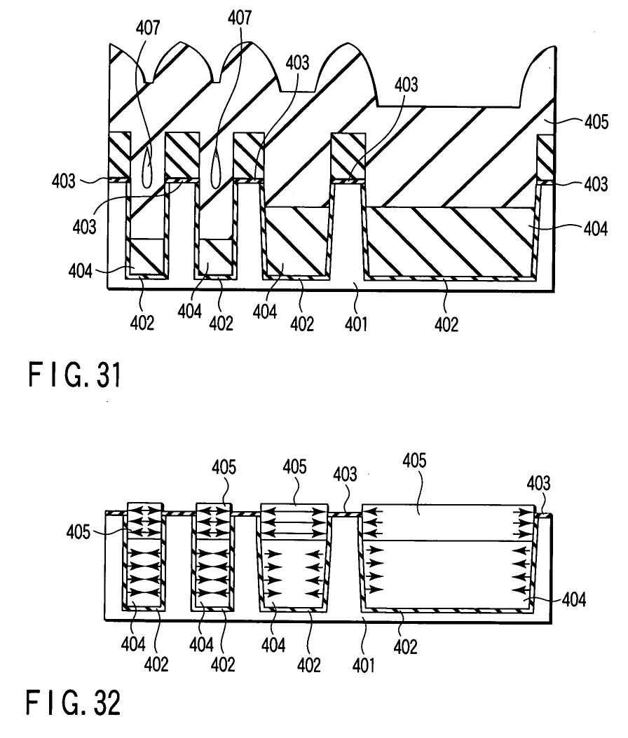

FIGS. 30 and 31 are cross sectional views of comparison samples where the SOG films 404 are etched back by wet etching.

The wet etching rate of the SOG films 404 depends on the width of the separated trenches. That is, the wet etching rate of the SOG film 404 in the narrow trench is larger than the wet etching rate of the SOG film 404 in the wide trench.

Therefore, if the control for the thickness of the SOG film 404 after the etch back in the narrow trench is given priority, the thickness of the SOG film 404 after the etch back in the narrow trench becomes too small. As the result, as shown in FIG. 31, voids 407 are generated when the HDP silicon oxide film 405 is formed.

[FIG. 5]

Next, a thermal silicon oxide film 107 having a thickness of 3 nm is formed by dry oxidization process at 750° C. using a diffusion furnace follows. At this time, a bird's beak is generated in a vicinity of interface between the upper surface of the polysilazane film 106 and the side surface of the isolation trench of the silicon substrate, and the thermal silicon oxide film 107 having a thickness of 4 nm is formed on the vicinity of interface.

That is, the thermal silicon oxide film 107 having the bird's beak shape, which becomes thick locally at the vicinity of the interface, is formed. A HDP silicon oxide film 108 is formed on the polysilazane film 106 in a later step. The thermal silicon oxide films 104, 107 turn out to be provided between the isolation trench and the isolation insulating film (polysilazane film 106, HDP silicon oxide film 108). Therefore, the thickness of thermal silicon oxide films 104, 107 becomes thicker on a portion of surface of the isolation trench which corresponds to an interface portion between the polysilazane film 106 and the HDP silicon oxide film 108 than other portion of the surface. To obtain the bird's beak shape, it requires dry oxidization at lower temperature such as 750°.

A sample including a silicon oxide film instead of the thermal silicon oxide film 107. The silicon oxide film is formed by a water vapor radical oxidation at 900° and has a thickness of 3 nm. The generation of bird's beaks of the silicon oxide film is suppressed.

[FIG. 6]

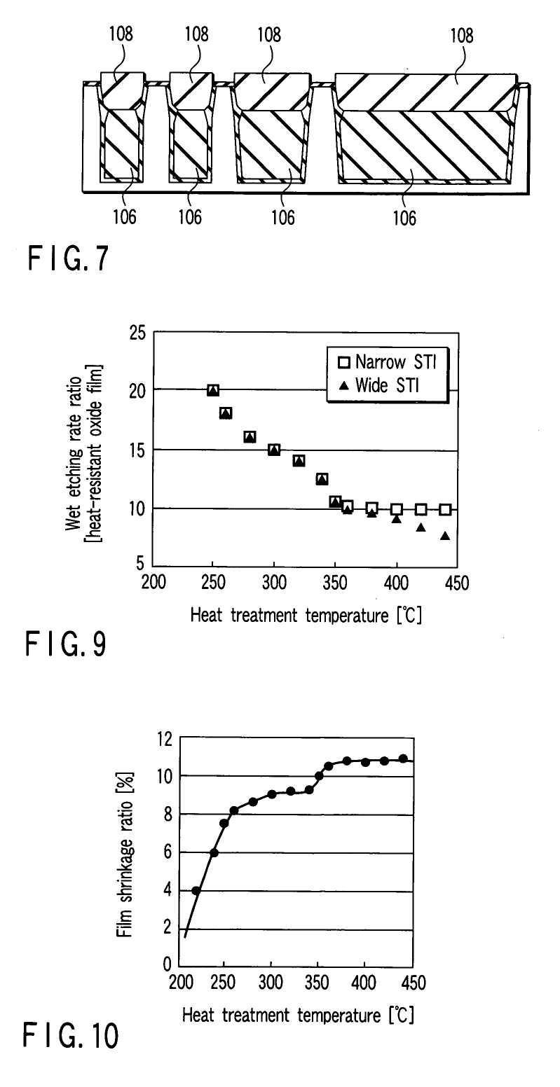

Next, the silicon nitride film 103 is etched back by 5 nm in a hot phosphoric acid solution, thus a lateral projection portion of the silicon nitride film 103 is removed. Thereafter, the HDP silicon oxide film 108 having a thickness of 500 nm is deposited on the entire surface, thus the isolation trench is completely filled with the HDP silicon oxide film 108.

[FIG. 7]

Next, the HDP silicon oxide film 108 is planarized by CMP process. Next the HDP silicon oxide film 108 is etched back by wet etching, thus the HDP silicon oxide film 108 having a desired thickness is formed. Next, the silicon nitride film 103 is removed in a hot phosphoric acid solution, thus the STI region is formed.

During the wet etching, the upper portion of the STI is protected by the HDP silicon oxide film 108. Thereby, the STI is hard to be thinned when subjected two or more times of wet etching such as the multi oxide process.

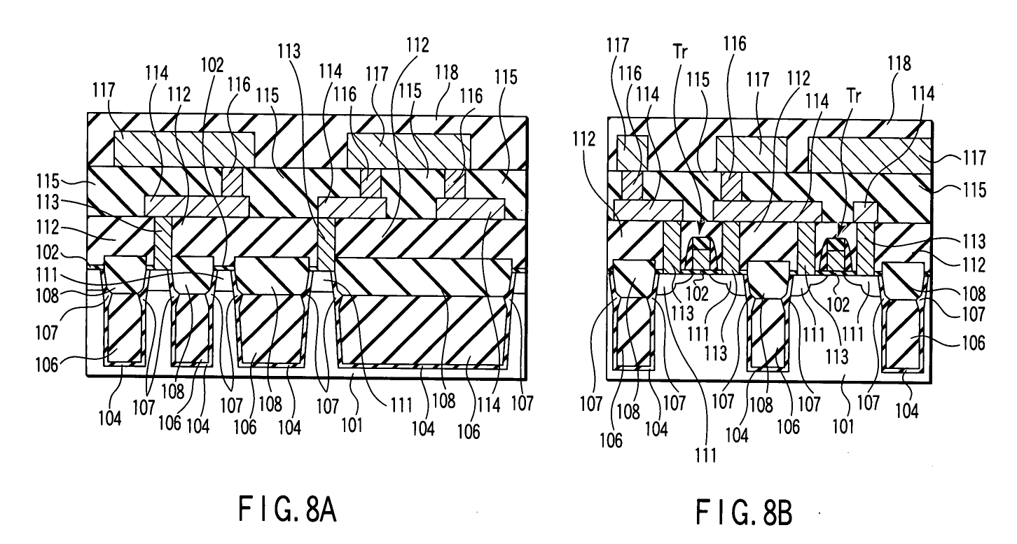

Thereafter, conventional step of forming a device such as a transistor is followed, thus the semiconductor device shown in FIGS. 8A and 8B are obtained. The transistor is for example a transistor in a memory cell in a trench DRAM or embedded trench DRAM (embedded LSI).

In FIGS. 8A and 8B, Tr indicates a transistor, 111 indicates a source/drain including an extension, 112 indicates an insulating film called as PMD (pre-metal dielectric), 113 indicates a contact plug, 114 indicates a metal wiring (first wiring layer), 115 indicates an insulating film (first ILD film) called as ILD (interlayer dielectric), 116 indicates a contact plug, 117 indicates a metal wiring (second wiring layer), and 118 indicates an insulating film (second ILD film) called as insulating ILD.

The inventors evaluate a junction leakage of the present embodiment and the junction leakage of the comparison sample with the bird's beaks suppressed. As the result, in the case of the present embodiment, the junction leakage is 10 fA/μm (with 5V applied), in the case of the comparison sample, the junction leakage is 22 fA/μm (with 5V applied) That is, it is proved that present embodiment can suppress the junction leakage to ½ as compared with the comparison sample, thus present embodiment can sufficiently suppress the junction leakage.

The reason why the above result is obtained is considered as follows. In a case of the present embodiment, a concentration of stress caused by discontinuity of the interface between the polysilazane film and the HDP silicon oxide film is released by generating the bird's beak, as the result of it, crystal defects is supposed to be suppressed.

FIG. 32 is a cross sectional view of the sample of comparison example. In the sample, the stress concentrates on an interface between the SOG film 404 and the HDP silicon oxide film 405 because of the influence of stress (compressive stress, tensile stress) caused by difference of film property between the SOG film 404 and the HDP silicon oxide film 405. By the concentration of the stress, the junction leakage is brought about in the comparison example.

### Second Embodiment

FIGS. 12 to 18 are cross sectional views showing steps of a method of manufacturing a semiconductor device according to a second embodiment of the present invention.

The present embodiment explains a case where an STI is formed after a gate oxide film and a gate electrode are formed on a silicon substrate (gate first formed structure).

The gate first formed structure has an advantage that concentration of electric field at the gate edge is to be suppressed. However, the gate first formed structure has a disadvantage that problems such as thermal degradation of the gate oxide film or generation of the bird's beak at the edge of the gate oxide film by heating step for forming the STI tend to occur.

In the present embodiment, an HTO film is formed on the inner surface (side surface and bottom surface) of the isolation trench (shallow trench) before the isolation trench is filled with the polysilazane film. Thereby, the gate oxide film is protected and the HDP silicon oxide film is easily filled. The second embodiment will be described below in more detail.

[FIG. 12]

At first, a gate oxide film 202 is formed on a silicon substrate 201, thereafter, a polycrystalline silicon film 203 having a thickness of 150 nm to be a gate electrode, a silicon nitride film 204 having a thickness of 100 nm used as CMP stopper in CMP process are sequentially formed on the gate oxide film 202.

Next, a CVD silicon oxide film to be a mask in the RIE (Reactive Ion Etching) process is formed on an entire surface of the substrate, thereafter, a photo resist film is applied on the CVD silicon oxide film.

Next, the photo resist film is processed by conventional lithographic process, thereafter, the CVD silicon oxide film is etched by the RIE process using the processed photo resist film (resist pattern), thus a hard mask is formed. Thereafter, the photo resist film is removed by ashing process and etching process with a sulfuric acid/hydrogen peroxide mixture solution.

Next, the silicon nitride film 204, polycrystalline silicon film 203, the gate oxide film 202, and the silicon substrate 201 are etched sequentially by the RIE process using the hard mask (the CVD silicon oxide film) as a mask, thus a trench (shallow trench) of 200 nm depth is formed on the surface of the silicon substrate 201. Thereafter, the hard mask is selectively removed by a vapor of fluoric acid.

Next, an inner surface of the trench (exposed surfaces of the silicon substrate 201 and polycrystalline silicon film 203) is thermally oxidized, thus a thermal silicon oxide film 205 of 3 nm thickness is formed on the inner surface.

After the foregoing steps, an isolation trench 206 for STI is formed.

[FIG. 13]

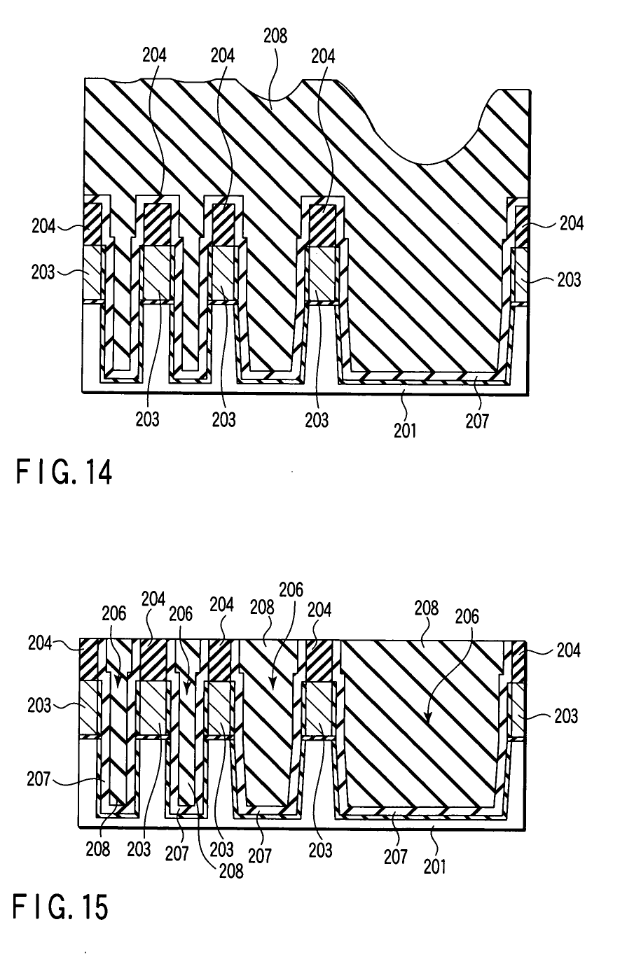

Next, an HTO (high temperature oxide) film 207 of 15 nm thick as a liner film is formed on the entire surface of the substrate. The HTO film 207 is formed, for example, by CVD process using SiH₄ and N₂O as source gas. As the liner film, a silicon oxide film may be used. Further, oxide film other than the HTO film 207 also may be used. By using the liner film, the influence of stress is reduced. Thereby, it makes possible to realize a favorable STI shape.

[FIG. 14]

Next, a coating film having a thickness of 600 nm to be a polysilazane film 206 is formed on the entire surface by spin coating process. The method of forming the coating film is identical to that of the first embodiment.

Next, a heating treatment is applied to the coating film in a water vapor atmosphere at a temperature from 250° C. to 350° C. In the present embodiment, the heat treatment process is performed in a water vapor atmosphere at 300° C. for 30 minutes.

By the heat treatment, the impurity carbons or hydrocarbons in the coating film are removed, further, most of Si—N bonds in the coating film are changed into Si—O bonds. This reaction takes a progress as in expressed below.
SiH₂NH+2O→SiO₂+NH₃.

By the reaction and thermal shrinkage, the coating film is densified and turned to a polysilazane film 208 which can be processed by CMP process.

[FIG. 15]

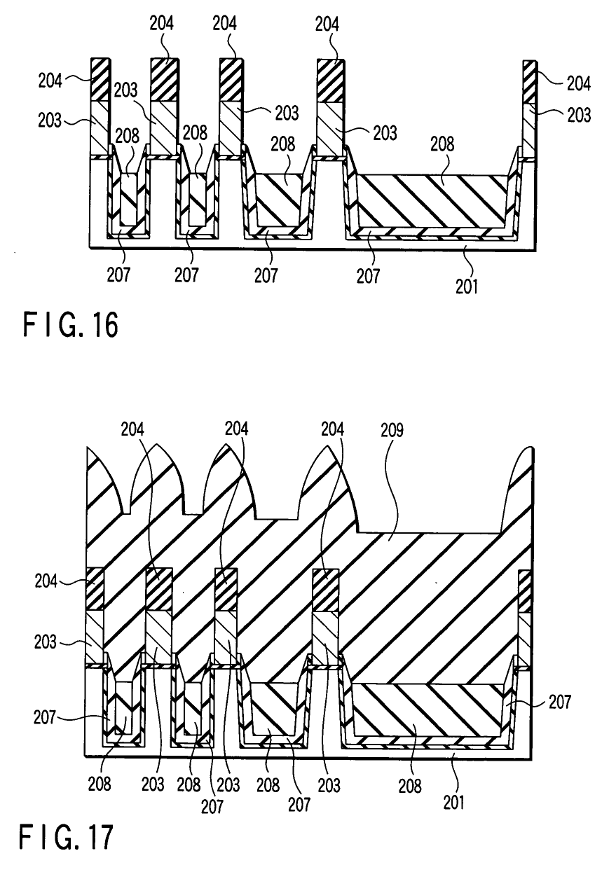

Next, the polysilazane film 208 and the HTO film 207 are polished by CMP process using the silicon nitride film 204 as a stopper, thus the polysilazane film 208 remains only in the isolation trench 206.

[FIG. 16]

Next, the polysilazane film 208 is etched back 350 nm by wet etching using a 100:1 diluted fluoric acid. At this time, it is desired that the polysilazane film 208 is etched back at the same rate regardless of the width of the isolation region so that the isolation trench is easily filled the HDP silicon oxide film 209 in a step of FIG. 17 which will be mentioned later.

Because, if the polysilazane film 208 in the narrow isolation trench is etched back more than the polysilazane film 208 in the wide isolation trench, the wide isolation trench is not etched back enough in depth or the narrow isolation trench is excessively etched back in depth, therefore, it is supposed that HDP silicon oxide film is not sufficiently embedded.

In the present embodiment, as mentioned above, the oxidization (heat treatment) in the water vapor atmosphere at 300° C. for 30 minutes is performed to the polysilazane film 208 in the step of FIG. 14. In this case, density of polysilazane film 208: 5.9×10²² cm⁻³, shrinkage of polysilazane film 208: 8.0%, selectivity of wet etching using 100:1 diluted fluoric acid solution to thermal silicon oxide film: 15 are obtained.

The etching selectivity to the thermal oxide film is equal among the different isolation widths of the trench regions of the isolation trench, and the remained film thickness of the polysilazane film 208 is 150 nm. Thereby, the polysilazane film 208 is regressed at a position which is lower than the bottom surface of the gate oxide film 202. By regressing the polysilazane film 208 at the position lower than the bottom surface of the gate oxide film 202, the gate oxide film 202 is protected from the influence of the coating film such as impurities therein.

As the selectivity is realized, even after the polysilazane film 208 is etched back by wet etching, the HTO film 207 having a thickness of 5 nm or more remains on a side surface of the gate oxide film 202. The remained HTO film 207 thus protects the gate oxide film in the gate first structure from being eroded by the etching solution (multi gate oxidization process).

Further, as the etch back of the polysilazane film 208 is carried out with no use of dry process such as RIE process, no plasma damage is generated at the edge of the gate oxide film.

[FIG. 17]

Next, the HDP silicon oxide film 209 having a thickness of 500 nm is deposited on the entire surface, thus the isolation trench is completely filled with the HDP silicon oxide film 209. At this time, the remained HTO film 207 on the upper side surface of the isolation trench decreases its thickness toward upward. As the result, the isolation trench filled with the HDP silicon oxide film 209 is shaped in a taper form. This allows the HDP silicon oxide film 209 to be easily filled without generating voids.

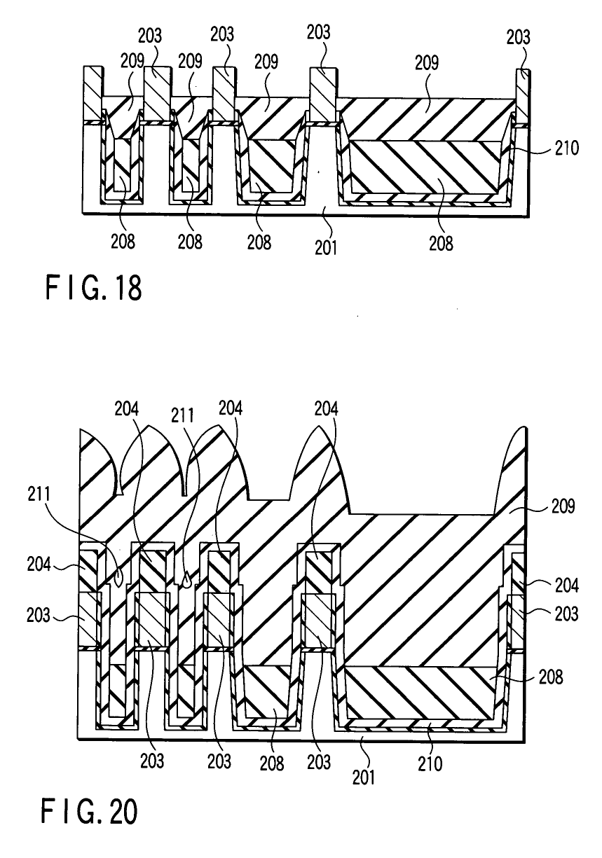

Also, as a sample for comparison example, as shown in FIG. 20, which includes an LPCVD silicon nitride film 210 of 15 nm thick as the liner film formed on the isolation trench having the similar shape as to the present embodiment, is formed. It is confirmed that a small voids 211 are generated in a center portion of STI region of the sample for the comparison example.

[FIG. 18]

Next, the HDP silicon oxide film 209 is planarized by CMP process. Next the HDP silicon oxide film 209 is etched back by wet etching, thus the HDP silicon oxide film 209 having a desired thickness is formed. Next, the silicon nitride film 204 is removed in a hot phosphoric acid solution, thus the STI region is formed.

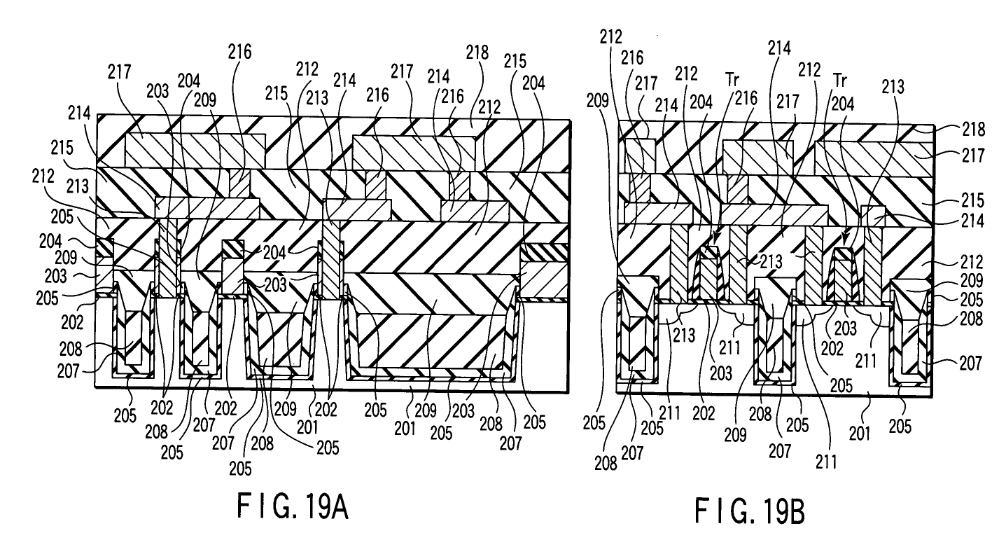

Thereafter, conventional step of forming a device such as a transistor is followed, thus the semiconductor device shown in FIGS. 19A and 19B are obtained. The transistor is for example a transistor in a memory cell in a trench DRAM or embedded trench DRAM (embedded LSI).

In FIGS. 19A and 19B, Tr indicates a transistor, 211 indicates a source/drain including an extension, 212 indicates an insulating film called as PMD, 213 indicates a contact plug, 214 indicates a metal wiring (first wiring layer), 215 indicates an insulating film (first ILD), 216 indicates a contact plug, 217 indicates a metal wiring (second wiring layer), and 218 indicates an insulating film (second ILD film).

### Third Embodiment

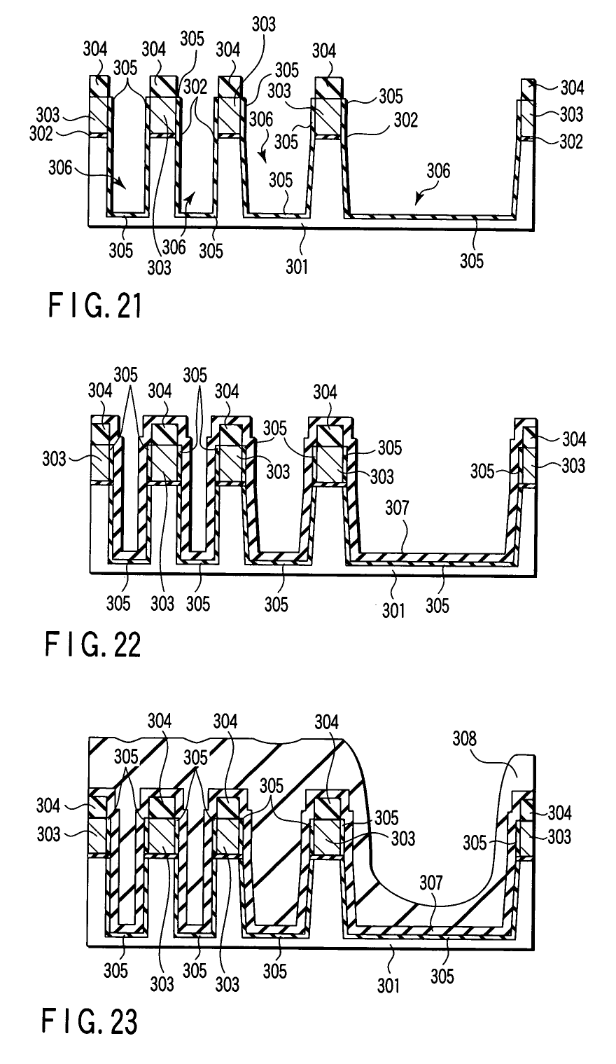

FIGS. 21 to 26 are cross sectional views showing steps of a method of manufacturing a semiconductor device according to a second embodiment of the present invention.

The present embodiment explains the case where the STI is formed after the gate oxide film and the gate electrode are formed on the silicon substrate (gate first formed structure) as in the second embodiment. In the present embodiment, the coating film thickness for the polysilazane film is controlled not like the second embodiment. Thereby, the CMP process which is repeated two times in the first and second embodiments is reduced to one time. The present embodiment will be explained below in more detail.

[FIG. 21]

At first, as in the second embodiment, a gate oxide film 302, a polycrystalline silicon film 303 having a thickness of 100 nm to be a gate electrode, and a silicon nitride film 304 having a thickness of 50 nm to be a CMP stopper are formed on a silicon substrate 301.

Here, the reason why the thickness of the silicon nitride film 304 is small not like the second embodiment is as follows. In the method of the present embodiment, the CPM process is performed only once. Therefore, the silicon nitride film 304 works as the polishing stopper even though the thickness of the silicon nitride film 304 is small.

Next, the silicon nitride film 304, the polycrystalline silicon film 303, the gate oxide film 302, and the silicon substrate 301 are processed by lithographic process and RIE process, thus a trench of 200 nm depth (shallow trench) is formed on surface of the silicon substrate 301, Further, a thermal silicon oxide film 305 of 4 nm thick is formed on an inner surface of the trench by thermal oxidation process.

After the foregoing steps, an isolation trench 306 for STI is formed.

[FIG. 22]

Next, as in the second embodiment, an HTO (high temperature oxide) film 307 of 15 nm thick as a liner film is formed on the entire surface of the substrate. As the liner film, a silicon oxide film may be used. By using the liner film, the influence of stress is reduced. Thereby, it makes possible to realize a favorable STI shape.

[FIG. 23]

Next, a coating film having a thickness of 200 nm to be a polysilazane film 308 is formed on the entire surface by spin coating process. The method of forming the coating film is the same to that of the first embodiment.

At this time, by forming the coating film to be a polysilazane film 308 thinly, the narrow isolation trench is nearly completely filled with polysilazane film 308, but the narrow isolation trench is partially filled with the polysilazane film 308.

Next, a heating treatment is applied to the coating film in a water vapor ambient at a temperature from 250° C. to 350° C. In the present embodiment, the heat treatment process is performed in a water vapor atmosphere at 300° C. for 30 minutes.

By the heat treatment, the impurity carbons or hydrocarbons in the coating film are removed, further, most of Si—N bonds in the coating film are changed into Si—O bonds. This reaction takes a progress as in expressed below.
SiH₂NH+2O→SiO₂+NH₃.

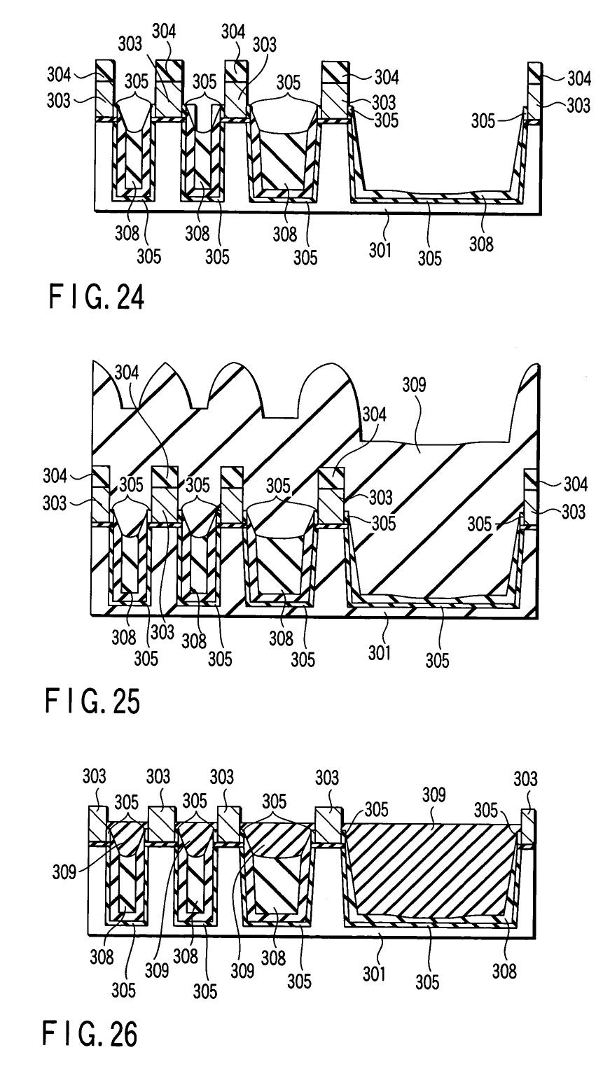

By the reaction and thermal shrinkage, the coating film is densified and turned to a polysilazane film 308 which can be processed by CMP process.

[FIG. 24]

Next, the polysilazane film 308 is etched back 250 nm by wet etching using a 100:1 diluted fluoric acid. At this time, the polysilazane film 208 is etched back at the same rate regardless of the width of the isolation trench. Thereby, the polysilazane film 308 remains by 150 nm in the narrow isolation trench, thus the bottom up of the isolation trench is realized. On the other hand, the polysilazane film 308 in the wide isolation trench is nearly completely removed.

In the present embodiment, as mentioned above, the oxidization (heat treatment) in the water vapor atmosphere at 300° C. for 30 minutes is performed to the polysilazane film 308 in the step of FIG. 23. In this case, density of polysilazane film 308: 5.9×10²² cm⁻³, shrinkage of polysilazane film 308: 8.0%, selectivity of wet etching using 100:1 diluted fluoric acid solution to thermal silicon oxide film: 15 are obtained.

As the selectivity is realized, even after the polysilazane film 308 is etched back by wet etching, the HTO film 307 having a thickness of 5 nm or more remains on a side surface of the gate oxide film 302. The remained HTO film 307 thus protects the gate oxide film from being eroded by the etching solution. Further, in the wide isolation trench, the sufficiently high selectivity between the polysilazane film 308 and the HTO film 307 is secured, thus the polysilazane film 308 is selectively removed without the substrate surface being exposed (thickness of remained HTO film on the bottom portion of the wide isolation trench is 2 nm or more)

[FIG. 25]

Next, the HDP silicon oxide film 309 having a thickness of 500 nm is deposited on the entire surface, thus the isolation trench is completely filled with the HDP silicon oxide film 309. At this time, the remained HTO film 307 on the upper side surface of the isolation trench decreases its thickness toward upward. As the result, the isolation trench filled with the HDP silicon oxide film 209 is shaped in a taper form. This allows the filling without voids to be easily performed.

[FIG. 26]

Next, the HDP silicon oxide film 309 and HTO film 307 are planarized by CMP process. Next the HDP silicon oxide film 309 is etched back by wet etching, thus the HDP silicon oxide film 309 having a desired thickness is formed. Next, the silicon nitride film 303 is removed in a hot phosphoric acid solution, thus the STI region is formed.

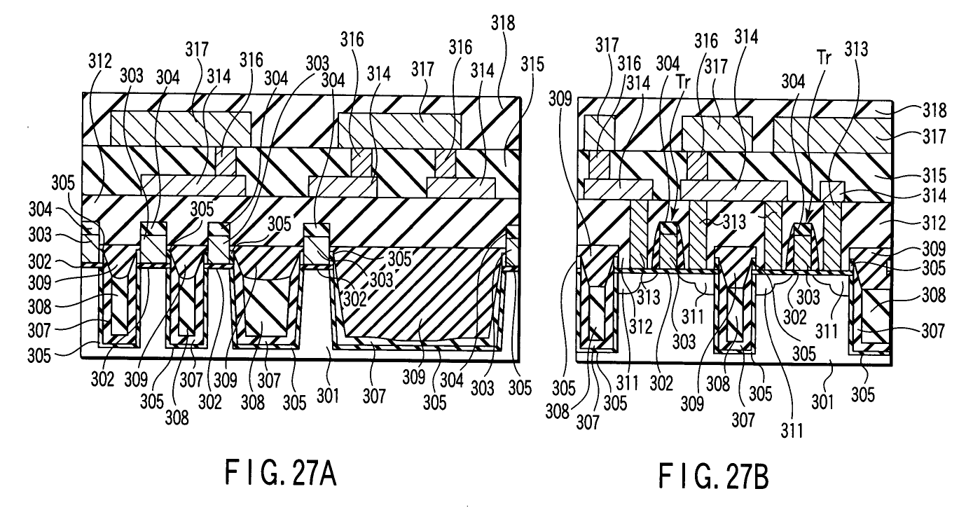

Thereafter, conventional step of forming a device such as a transistor is followed, thus the semiconductor device shown in FIGS. 27A and 27B are obtained. The transistor is for example a transistor in a memory cell in a trench DRAM or embedded trench DRAM (embedded LSI).

In FIGS. 27A and 27B, Tr indicates a transistor, 311 indicates a source/drain including an extension, 312 indicates an insulating film called as PMD, 313 indicates a contact plug, 314 indicates a metal wiring (first wiring layer), 315 indicates an insulating film (first ILD), 316 indicates a contact plug, 317 indicates a metal wiring (second wiring layer), and 318 indicates an insulating film (second ILD film).

The present invention is not limited to the foregoing embodiments. For example, the silicon semiconductor substrate in the embodiment may be replaced by any other semiconductor substrate such as an SOI substrate or a semiconductor substrate including a SiGe region in an active area.

Further, in the foregoing embodiments, the polysilazane film is used as the coating film, however, a coating film formed by chemical solution which is different from that of the foregoing embodiments may be used if the coating film has the film density defined by the present invention or the wet etching selectivity to the liner film defined by the present invention.

Further, in the foregoing embodiments, the polysilazane film is used as the coating film, however, a silica based coating film other than the polysilazane film may be used. In this case, as in the case of polysilazane film, the isolation trench is filled with the silica based coating film, thereafter, the heat treatment step is performed under at least one of condition that shrinkage ratio of the silica based coating film is not higher than the predetermined value and condition that film density of the silica based coating film is not higher than the predetermined value, thereby, the etching rate of the silica based coating film can be nearly same regardless of the width of the isolation trench.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor device comprising:
a semiconductor substrate including an isolation trench provided on a surface thereof;
an isolation film provided in the isolation trench, the isolation film including a coating film and a silicon oxide film provided on the coating film; and
an oxide film provided between the isolation trench and the isolation film, the oxide film having a thickness such that a portion on a side surface of the isolation trench corresponding to an interface portion between the coating film and the silicon oxide film is thicker than other portion on the side surface.

2. The semiconductor device according to claim 1, wherein the oxide film on the side surface of the isolation trench corresponding to the interface portion includes a bird's beak shape.

3. The semiconductor device according to claim 1, wherein the silicon oxide film is an HDP silicon oxide film.

4. A semiconductor device comprising:
a semiconductor substrate including an isolation trench provided on a surface thereof;
an isolation film provided in the isolation trench, the isolation film including a coating film and a silicon oxide film provided on the coating film; and
a liner film provided between the isolation trench and the isolation film, the liner film having a thickness such that a portion on an upper surface of the isolation trench decreases upward.

5. The semiconductor device according to claim 1, wherein the coating film is a coating film of a perhydro silazane polymer.

6. The semiconductor device according to claim ˜4, wherein the liner oxide film is an HDP silicon nitride film or a silicon nitride film.

7. The semiconductor device according to claim 4, wherein a density of the coating film is not higher than 6.0×10²³ cm⁻³.

8. A method of manufacturing a semiconductor device, comprising:
forming an isolation trench on a surface of a semiconductor substrate;
filling the isolation trench with a coating film;
heating the coating film under at least one of condition that shrinkage ratio of the coating film is not higher than a predetermined value and condition that film density of the coating film is not higher than a predetermined value;
removing an upper portion of the coating film in the isolation trench by etch back using wet etching;
forming a silicon oxide film on the semiconductor substrate so as to fill the isolation trench; and
planarizing the silicon oxide film by CMP process.

9. The method of manufacturing the semiconductor device according to claim 8, wherein the coating film is a coating film of a perhydro silazane polymer, and the heating the coating film includes heating the coating film under an atmosphere containing mainly water vapor.

10. The method of manufacturing the semiconductor device according to claim 8, wherein the coating film is a coating film of a perhydro silazane polymer, and the heating the coating film includes heating the coating film under an atmosphere containing mainly water vapor under at least one of condition that shrinkage ration of the coating film is not higher than 10% and condition that film density of the coating film is not higher than 6.0×10²³ cm⁻³.

11. The method of manufacturing the semiconductor device according to claim 10, wherein the coating film is a coating film of a perhydro silazane polymer, and the heating the coating film under the atmosphere containing mainly the water vapor includes setting the temperature of the atmosphere in a range of 250° C. to 350° C.

12. The method of manufacturing the semiconductor device according to claim 8, wherein the silicon oxide film is formed by high density plasma CVD process.

13. The method of manufacturing the semiconductor device according to claim 8, further comprising: oxidizing the semiconductor substrate of a side surface of the isolation trench, the side surface being a surface exposed by the etch back used for removing the upper portion of the coating film in the isolation trench.

14. The method of manufacturing the semiconductor device according to claim 8, further comprising: covering an inner surface of the isolation trench with a liner film before filling the isolation trench with the coating film.

15. The method of manufacturing the semiconductor device according to claim 14, wherein the liner film is an HTO film or a silicon nitride film.

16. The method of manufacturing the semiconductor device according to claim 8, wherein the removing the upper portion of the coating film in the isolation trench by the etch back using the wet etching includes setting the wet etching rate ratio of the coating film to a thermal oxide film not smaller than 10.

17. The method of manufacturing the semiconductor device according to claim 8, further comprising:
forming a gate oxide film and a gate electrode on the semiconductor substrate before the forming the isolation trench

18. The method of manufacturing the semiconductor device according to claim 17, wherein a position of uppermost surface of the coating film filling the isolation trench is lower than a position of lowermost surface of the gate oxide film.

19. The method of manufacturing the semiconductor device according to claim 8, wherein the isolation trench include a first trench region having a first isolation width and a second trench region having a second isolation width being wider than the first isolation width.

20. The method of manufacturing the semiconductor device according to claim 19, wherein the filling the isolation trench with the coating film includes filling substantially completely the first trench region with the coating film and filling partway the second trench region with the coating film.
